(19) United States
(12) Patent Application Publication
(10) Pub. No.: US 2023/0349762 A1
(43) Pub. Date: Nov. 2, 2023

(54) LASER SYSTEM, SPECTRUM WAVEFORM CALCULATION METHOD, AND ELECTRONIC DEVICE MANUFACTURING METHOD

(71) Applicant: Gigaphoton Inc., Tochigi (JP)

(72) Inventors: Natsuhiko KOUNO, Oyama-shi (JP); Shunya OIWA, Oyama-shi (JP); Masato MORIYA, Oyama-shi (JP)

(73) Assignee: Gigaphoton Inc., Tochigi (JP)

(21) Appl. No.: 18/351,712

(22) Filed: Jul. 13, 2023

Related U.S. Application Data
(63) Continuation of application No. PCT/JP2021/005126, filed on Feb. 11, 2021.

(51) Int. Cl. G01J 3/44; H01S 3/082; H01S 3/106; B23K 26/70

(52) U.S. Cl. CPC G01J 3/4406; H01S 3/0826; H01S 3/1067; B23K 26/705; G01J 2009/0238

(57) ABSTRACT

A laser system connectable to an exposure apparatus includes a spectrometer configured to acquire a measurement waveform from an interference pattern of laser light output from the laser system, and a processor configured to calculate a convolution spectrum waveform using the measurement waveform and a first intermediate function obtained through a process of deconvolution of an aerial image function of the exposure apparatus with an instrument function of the spectrometer.

### CROSS-REFERENCE TO RELATED APPLICATIONS

The present application claims the benefit of International Application No. PCT/JP2021/005126, filed on Feb. 11, 2021 the entire contents of which are hereby incorporated by reference.

### BACKGROUND

### 1. Technical Field

The present disclosure relates to a laser system, a spectrum waveform calculation method, and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectrum line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectrum line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectrum line width. In the following, a gas laser device with a narrowed spectrum line width is referred to as a line narrowing gas laser device.

### LIST OF DOCUMENTS

### Patent Documents

Patent Document 1: US Patent Application Publication No. 2011/200922
Patent Document 2: Japanese Patent Application Publication No. 2003-243752
Patent Document 3: US Patent Application Publication No. 2007/273852

### SUMMARY

A laser system connectable to an exposure apparatus according to an aspect of the present disclosure includes a spectrometer configured to acquire a measurement waveform from an interference pattern of laser light output from the laser system, and a processor configured to calculate a convolution spectrum waveform using the measurement waveform and a first intermediate function obtained through a process of deconvolution of an aerial image function of the exposure apparatus with an instrument function of the spectrometer.

A spectrum waveform calculation method according to an aspect of the present disclosure includes causing laser light output from a laser system connectable to an exposure apparatus to be incident on a spectrometer, acquiring a measurement waveform from an interference pattern of the laser light by the spectrometer, and calculating a convolution spectrum waveform using the measurement waveform and a first intermediate function obtained through a process of deconvolution of an aerial image function of the exposure apparatus with an instrument function of the spectrometer.

An electronic device manufacturing method according to an aspect of the present disclosure includes generating laser light using a laser system, outputting the laser light to an exposure apparatus, and exposing a photosensitive substrate to the laser light in the exposure apparatus to manufacture an electronic device. Here, the laser system includes a spectrometer configured to acquire a measurement waveform from an interference pattern of the laser light output from the laser system connectable to the exposure apparatus, and a processor configured to calculate a convolution spectrum waveform using the measurement waveform and a first intermediate function obtained through a process of deconvolution of an aerial image function of the exposure apparatus with an instrument function of the spectrometer.

### BRIEF DESCRIPTION OF THE DRAWINGS

Embodiments of the present disclosure will be described below merely as examples with reference to the accompanying drawings.

FIG. 1 schematically shows the configuration of a laser system according to a comparative example.

FIG. 2 is a block diagram for explaining the function of the spectrum measurement processor in the comparative example.

FIG. 3 schematically shows the configuration of the laser system according to a first embodiment.

FIG. 4 is a block diagram for explaining the function of the spectrum measurement processor in the first embodiment.

FIG. 5 schematically shows the configuration of the laser system according to a second embodiment.

FIG. 6 is a block diagram for explaining the function of the spectrum measurement processor in the second embodiment.

FIG. 7 schematically shows the configuration of the laser system according to a third embodiment.

FIG. 8 shows the laser system with a first variation of a wavefront adjuster.

FIG. 9 shows the laser system with a second variation of the wavefront adjuster.

FIG. 10 shows the laser system with a third variation of the wavefront adjuster.

FIG. 11 shows the laser system with a fourth variation of the wavefront adjuster.

FIG. 12 schematically shows the configuration of the laser system according to a fourth embodiment.

FIG. 13 shows a line narrowing module including a variation of a mechanism for adjusting the beam width.

FIG. 14 shows the line narrowing module including the variation of the mechanism for adjusting the beam width.

FIG. 15 schematically shows the configuration of the laser system according to a fifth embodiment.

FIG. 16 schematically shows the configuration of the laser system according to a sixth embodiment.

FIG. 17 is a graph showing the relationship between the delay time of an oscillation trigger signal to a master oscillator and a power oscillator and the convolution spectrum line width of pulse laser light output from the power oscillator.

FIG. 18 schematically shows the configuration of an exposure apparatus connected to the laser system.

### DESCRIPTION OF EMBODIMENTS

### <Content>

1. Comparative example
   1.1 Configuration
      1.1.1 Laser resonator
      1.1.2 Monitor module 16
      1.1.3 Various processing devices
   1.2 Operation
      1.2.1 Laser control processor 30
      1.2.2 Laser resonator
      1.2.3 Monitor module 16
      1.2.4 Wavelength measurement control unit 50
      1.2.5 Spectrum measurement processor 60
   1.3 Problem of comparative example
2. Laser system 1a calculating convolution spectrum waveform C1(λ) using deconvolution aerial image function D(λ)
   2.1 Configuration
   2.2 Operation
   2.3 Description of C0(λ) and C1(λ) being equal to each other
   2.4 Effect
3. Laser system 1b calculating convolution spectrum waveform C2(λ) using Fourier transform F(D(λ)) of deconvolution aerial image function D(λ))
   3.1 Configuration
   3.2 Operation
   3.3 Description of C2(λ) being equal to each of C0(λ) and C1 (A)
   3.4 Effect
4. Laser system 1c including adjustment mechanism of spectrum line width by wavefront adjustment
   4.1 Configuration
   4.2 Operation
   4.3 Variations of wavefront adjuster
      4.3.1 Wavefront adjuster 15e arranged between output coupling mirror 15 and laser chamber 10
      4.3.2 Wavefront adjuster 15h configured of deformable mirror
      4.3.3 Wavefront adjuster 15e arranged between line narrowing module 14 and laser chamber 10
      4.3.4 Grating 141 capable of changing shape thereof
   4.4 Effect
5. Laser system 1h including adjustment mechanism of spectrum line width by beam width adjustment
   5.1 Configuration
   5.2 Operation
   5.3 Adjustment mechanism of spectrum line width for changing beam width by replacing prisms 144, 147
   5.4 Effect
6. Laser system 1j including adjustment mechanism of spectrum line width by fluorine partial pressure
   6.1 Configuration
   6.2 Operation
   6.3 Effect
7. Laser system 1k including master oscillator MO and power oscillator PO
   7.1 Configuration
   7.2 Operation
      7.2.1 Laser control processor 30
      7.2.2 Master oscillator MO
      7.2.3 Power oscillator PO
      7.2.4 Spectrum measurement control processor 60c
   7.3 Effect
8. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Comparative Example

### 1.1 Configuration

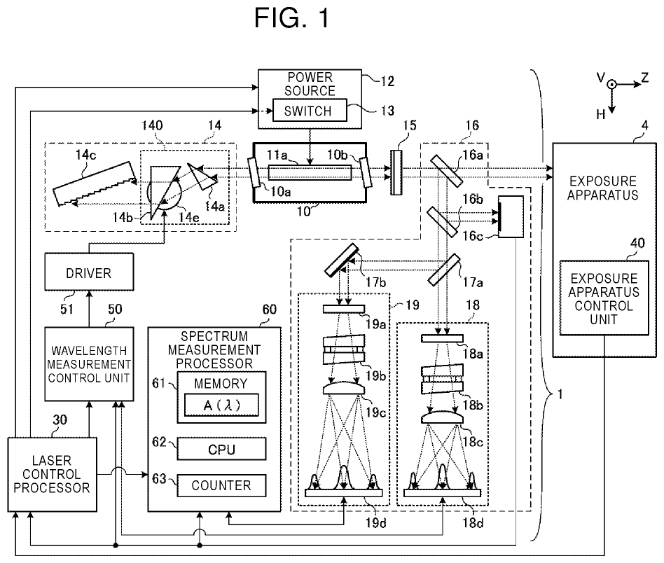

FIG. 1 schematically shows the configuration of a laser system 1 according to a comparative example. The comparative example of the present disclosure is an example recognized by the applicant as known only by the applicant, and is not a publicly known example admitted by the applicant. The laser system 1 includes a laser chamber 10, a discharge electrode 11a, a power source 12, a line narrowing module 14, an output coupling mirror 15, a monitor module 16, a laser control processor 30, a wavelength measurement control unit 50, and a spectrum measurement processor 60. The laser system 1 is connectable to an exposure apparatus 4.

### 1.1.1 Laser Resonator

The line narrowing module 14 and the output coupling mirror 15 configure a laser resonator. The laser chamber 10 is arranged on the optical path of the laser resonator. Windows 10a, 10b are arranged at both ends of the laser chamber 10. The discharge electrode 11a and a discharge electrode (not shown) paired therewith are arranged inside the laser chamber 10. The discharge electrode (not shown) is positioned so as to overlap with the discharge electrode 11a in the direction of the V axis perpendicular to the paper surface. The laser chamber 10 is filled with a laser gas containing, for example, an argon gas or a krypton gas as a rare gas, a fluorine gas as a halogen gas, a neon gas as a buffer gas, and the like.

The power source 12 includes a switch 13 and is connected to the discharge electrode 11a and a charger (not shown).

The line narrowing module 14 includes a beam expander 140 and a grating 14c. The beam expander 140 includes a plurality of prisms 14a, 14b. The prism 14b is supported by a rotation stage 14e. The rotation stage 14e is configured to rotate the prism 14b about an axis parallel to the V axis in accordance with a drive signal output from a driver 51. By rotating the prism 14b, the selected wavelength of the line narrowing module 14 is changed.

The output coupling mirror 15 is made of a material that transmits light having a wavelength selected by the line narrowing module 14, and one surface thereof is coated with a partial reflection film.

### 1.1.2 Monitor Module 16

The monitor module 16 is arranged on the optical path of the pulse laser light between the output coupling mirror 15 and the exposure apparatus 4. The monitor module 16 includes beam splitters 16a, 16b, 17a, an energy sensor 16c, a high reflection mirror 17b, a wavelength detector 18, and a spectrometer 19.

The beam splitter 16a is located on the optical path of the pulse laser light output from the output coupling mirror 15. The beam splitter 16a is configured to transmit a part of the pulse laser light output from the output coupling mirror 15 toward the exposure apparatus 4 at high transmittance and to reflect other parts thereof. The beam splitter 16b is located on the optical path of the pulse laser light reflected by the beam splitter 16a. The energy sensor 16c is located on the optical path of the pulse laser light reflected by the beam splitter 16b.

The beam splitter 17a is located on the optical path of the pulse laser light transmitted through the beam splitter 16b. The high reflection mirror 17b is located on the optical path of the pulse laser light reflected by the beam splitter 17a.

The wavelength detector 18 is arranged on the optical path of the pulse laser light transmitted through the beam splitter 17a. The wavelength detector 18 includes a diffusion plate 18a, an etalon 18b, a light concentrating lens 18c, and a line sensor 18d.

The diffusion plate 18a is located on the optical path of the pulse laser light transmitted through the beam splitter 17a. The diffusion plate 18a has a plurality of irregularities on the surface thereof and is configured to transmit and diffuse the pulse laser light. The etalon 18b is located on the optical path of the pulse laser light transmitted through the diffusion plate 18a. The etalon 18b includes two partial reflection mirrors. The two partial reflection mirrors face each other with an air gap of a predetermined distance, and are bonded to each other with a spacer interposed therebetween.

The light concentrating lens 18c is located on the optical path of the pulse laser light transmitted through the etalon 18b. The line sensor 18d is located on the optical path of the pulse laser light transmitted through the light concentrating lens 18c and on the focal plane of the light concentrating lens 18c. The line sensor 18d is a light distribution sensor including a large number of light receiving elements arranged in one dimension. Alternatively, instead of the line sensor 18d, an image sensor including a large number of light receiving elements arranged in two dimensions may be used as the light distribution sensor.

The line sensor 18d receives interference fringes formed by the etalon 18b and the light concentrating lens 18c. The interference fringes form an interference pattern of the pulse laser light, and have a concentric shape, and a square of a distance from the center of the concentric circles is proportional to a change in wavelength.

The spectrometer 19 is arranged on the optical path of the pulse laser light reflected by the high reflection mirror 17b. The spectrometer 19 includes a diffusion plate 19a, an etalon 19b, a light concentrating lens 19c, and a line sensor 19d. Configurations thereof are the same as those of the diffusion plate 18a, the etalon 18b, the light concentrating lens 18c, and the line sensor 18d included in the wavelength detector 18. However, the etalon 19b has a free spectral range smaller than that of the etalon 18b. Also, the light concentrating lens 19c has a longer focal length than that of the light concentrating lens 18c.

### 1.1.3 Various Processing Devices

The spectrum measurement processor 60 is a processing device including a memory 61 in which a control program is stored, a central processing unit (CPU) 62 which executes the control program, and a counter 63. The spectrum measurement processor 60 is specifically configured or programmed to perform various processes included in the present disclosure. The spectrum measurement processor 60 corresponds to the processor in the present disclosure.

The memory 61 also stores various data for calculating the spectrum line width. The various data include an aerial image function A(λ) of the exposure apparatus 4. The counter 63 counts the number of pulses of the pulse laser light by counting the number of times of reception of the electric signal including the data of the pulse energy output from the energy sensor 16c. Alternatively, the counter 63 may count the number of pulses of the pulse laser light by counting the oscillation trigger signals output from the laser control processor 30.

The wavelength measurement control unit 50 is a processing device including a memory (not shown) in which a control program is stored, a CPU (not shown) that executes the control program, and a counter (not shown). Similarly to the counter 63, the counter included in the wavelength measurement control unit 50 also counts the number of pulses of the pulse laser light.

The laser control processor 30 is a processing device including a memory (not shown) in which a control program is stored, and a CPU (not shown) that executes the control program. The laser control processor 30 is specifically configured or programmed to perform various processes included in the present disclosure.

In the present disclosure, the laser control processor 30, the wavelength measurement control unit 50, and the spectrum measurement processor 60 are described as separate components. However, the laser control processor 30 may also serve as the wavelength measurement control unit 50 and the spectrum measurement processor 60.

### 1.2 Operation

### 1.2.1 Laser Control Processor 30

The laser control processor 30 receives setting data of the target pulse energy and the target wavelength of the pulse laser light from an exposure apparatus control unit 40 included in the exposure apparatus 4. The laser control processor 30 receives a trigger signal from the exposure apparatus control unit 40.

The laser control processor 30 transmits, to the power source 12, setting data of an application voltage to be applied to the discharge electrode 11a based on the target pulse energy. The laser control processor 30 transmits setting data of the target wavelength to the wavelength measurement control unit 50. Further, the laser control processor 30 transmits, to the switch 13 included in the power source 12, an oscillation trigger signal based on the trigger signal.

### 1.2.2 Laser Resonator

The switch 13 is turned on when the oscillation trigger signal is received from the laser control processor 30. When the switch 13 is turned on, the power source 12 generates a pulse high voltage from the electric energy charged in a charger (not shown), and applies the high voltage to the discharge electrode 11a.

When the high voltage is applied to the discharge electrode 11a, discharge occurs in the laser chamber 10. The laser medium in the laser chamber 10 is excited by the energy of the discharge and shifts to a high energy level. When the excited laser medium then shifts to a low energy level, light having a wavelength corresponding to the difference between the energy levels is emitted.

The light generated in the laser chamber 10 is output to the outside of the laser chamber 10 through the windows 10a, 10b. The beam width of the light output through the window 10a of the laser chamber 10 is expanded by the beam expander 140, and then the light is incident on the grating 14c. The light incident on the grating 14c from the beam expander 140 is reflected by a plurality of grooves of the grating 14c and is diffracted in a direction corresponding to the wavelength of the light.

The beam expander 140 reduces the beam width of the diffracted light from the grating 14c and returns the light to the laser chamber 10 through the window 10a. The output coupling mirror 15 transmits and outputs a part of the light output through the window 10b of the laser chamber 10, and reflects the other part back into the laser chamber 10.

In this way, the light output from the laser chamber 10 reciprocates between the line narrowing module 14 and the output coupling mirror 15, and is amplified each time the light passes through the discharge space in the laser chamber 10. The light is line narrowed each time being turned back in the line narrowing module 14. Thus, the light having undergone laser oscillation and line narrowing is output as pulse laser light from the output coupling mirror 15.

### 1.2.3 Monitor Module 16

The energy sensor 16c detects the pulse energy of the pulse laser light and outputs data of the pulse energy to the laser control processor 30, the wavelength measurement control unit 50, and the spectrum measurement processor 60. The data of the pulse energy is used by the laser control processor 30 to perform feedback control of the setting data of the application voltage to be applied to the discharge electrode 11a. An electric signal including the data of the pulse energy can be used by the wavelength measurement control unit 50 and the spectrum measurement processor 60 respectively to count the number of pulses.

The wavelength detector 18 generates waveform data of the interference fringes from the amount of light in each of the light receiving elements included in the line sensor 18d. The wavelength detector 18 may use the integrated waveform obtained by integrating the amount of light in each of the light receiving elements as the waveform data of the interference fringes. The wavelength detector 18 may generate the integrated waveform a plurality of times and use an average waveform obtained by averaging the plurality of integrated waveforms as the waveform data of the interference fringes. The wavelength detector 18 transmits the waveform data of the interference fringes to the wavelength measurement control unit 50 in accordance with a data output trigger output from the wavelength measurement control unit 50.

The spectrometer 19 generates an integrated waveform Oi obtained by integrating the amount of light in each of the light receiving elements included in the line sensor 19d over Ni pulses. The spectrometer 19 generates the integrated waveform Oi Na times and generates an average waveform Oa obtained by averaging the Na integrated waveforms Oi. The number of integrated pulses Ni is, for example, 5 pulses or more and 8 pulses or less, and the averaging number Na is, for example, 5 times or more and 8 times or less.

The counting of the number of integrated pulses Ni and the averaging number Na may be performed by the spectrum measurement processor 60, and the spectrometer 19 may generate the integrated waveform Oi and the average waveform Oa in accordance with a trigger signal output from the spectrum measurement processor 60. The memory 61 of the spectrum measurement processor 60 may store the setting data of the number of integrated pulses Ni and the averaging number Na.

The spectrometer 19 extracts a part of a waveform corresponding to a free spectral range from the average waveform Oa. The extracted part of the waveform shows the relationship between the distance from the center of the concentric circles constituting the interference fringes and the light intensity. The spectrometer 19 acquires the measurement waveform O(λ) of the spectrum by performing coordinate conversion of the waveform into the relationship between the wavelength and the light intensity. The coordinate conversion of a part of the average waveform Oa into the relationship between the wavelength and the light intensity is referred to as conversion into a wavelength space.

The spectrometer 19 transmits the measurement waveform O(λ) to the spectrum measurement processor 60 in accordance with a data output trigger output from the spectrum measurement processor 60. The process of acquiring the measurement waveform O(λ) by the conversion into the wavelength space may be performed by the spectrum measurement processor 60 instead of by the spectrometer 19. Both the process of generating the average waveform Oa and the process of acquiring the measurement waveform O(λ) may be performed by the spectrum measurement processor 60 instead of by the spectrometer 19.

### 1.2.4 Wavelength Measurement Control Unit 50

The wavelength measurement control unit 50 receives the setting data of the target wavelength from the laser control processor 30. Further, the wavelength measurement control unit 50 calculates the center wavelength of the pulse laser light using the waveform data of the interference fringes output from the wavelength detector 18. The wavelength measurement control unit 50 outputs a control signal to the driver 51 based on the target wavelength and the calculated center wavelength, thereby performing feedback control of the center wavelength of the pulse laser light.

### 1.2.5 Spectrum Measurement Processor 60

The spectrum measurement processor 60 receives the measurement waveform O(λ) from the spectrometer 19. The spectrum measurement processor 60 calculates an estimation spectrum waveform T0(λ) from the measurement waveform O(λ) in the following manner.

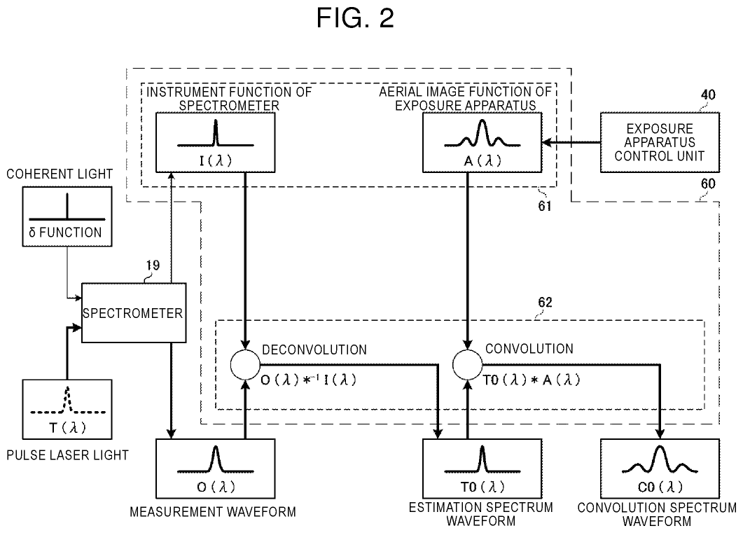

FIG. 2 is a block diagram for explaining the function of the spectrum measurement processor 60 in the comparative example. The spectrometer 19 has a measurement characteristic unique thereto, which is represented by an instrument function I(λ) as a function of the wavelength λ. Here, the measurement waveform O(λ) when the pulse laser light having an unknown spectrum waveform T(λ) is incident on the spectrometer 19 having the instrument function I(λ) and measured is represented by a convolution of the unknown spectrum waveform T(λ) and the instrument function I(λ) as follows.

O(λ)=∫_{-∞}^{∞}T(x)·I(λ−x)dλ

Here, ∫_{-∞}^{∞}Xdλ indicates the integral of X by the variable λ, from −∞ to ∞. That is, the convolution means a composite product of two functions. The convolution can be represented using the symbol*as follows:

O(λ)=T(λ)*I(λ)

The Fourier transform F(O(λ)) of the measurement waveform O(λ) is equal to the product of the Fourier transform F(T(λ)), F(I(λ)) of the two functions T(λ), I(λ), respectively, as follows:

F(O(λ))=F(T(λ))×F(I(λ))

This is called the convolution theorem.

The spectrum measurement processor 60 measures the instrument function I(λ) of the spectrometer 19 in advance and stores the instrument function I(λ) in the memory 61. In order to measure the instrument function I(λ), coherent light having substantially the same wavelength as the center wavelength of the pulse laser light output from the laser system 1 and having a narrow spectrum line width that can be substantially regarded as a δ function is caused to enter the spectrometer 19. The measurement waveform of the coherent light by the spectrometer 19 can be set as the instrument function I(λ).

The CPU 62 included in the spectrum measurement processor 60 performs deconvolution on the measurement waveform O(λ) of the pulse laser light with the instrument function I(λ) of the spectrometer 19. The deconvolution means an arithmetic process for estimating an unknown function satisfying the equation of convolution. That is, the unknown spectrum waveform T(λ) of the pulse laser light incident on the spectrometer 19 is estimated by deconvolution. The waveform obtained by deconvolution is referred to as the estimation spectrum waveform T0(λ). The estimation spectrum waveform T0(λ) is expressed as follows using the symbol *⁻¹ representing deconvolution.

T0(λ)=O(λ)*⁻¹I(λ)

Deconvolution can be calculated theoretically as follows. First, the following equation is derived from the convolution theorem.

F(T0(λ))=F(O(λ))/F(I(λ))

By performing the inverse Fourier transform on both sides of this equation, the calculation result of deconvolution is obtained. That is, assuming that the symbol of the inverse Fourier transform is F⁻¹, the estimation spectrum waveform T0(λ) is expressed as follows.

T0(λ)=F⁻¹(F(O(λ))/F(I(λ)))

However, in the actual numerical calculation, deconvolution using the Fourier transform and the inverse Fourier transform is easily affected by noise components included in the measurement data. Therefore, it is desirable to calculate deconvolution using an iterative method, such as the Jacobi method and the Gauss Seidel method), which can suppress the influence of noise components.

The CPU 62 may further calculate a convolution spectrum waveform C0(λ) of the estimation spectrum waveform T0(λ) and the aerial image function A(λ) of the exposure apparatus 4 as follows.

C0(λ)=T0(λ)*A(λ)

The aerial image function A(λ) is a mathematical expression of the aerial image of the pattern projected onto the photosensitive substrate by the exposure apparatus 4, and is expressed as a function of the wavelength h. An example of the aerial image function A(λ) of a contact hole is shown below.

A(λ)=exp(−a·λ²)·(cos(b·λ))²

Here, exp(X) is the power of Napier's constant with X as the exponent, and a and b are the following constants.
a=1.280
b=2.521

The spectrum measurement processor 60 may receive the aerial image function A(λ) from the exposure apparatus control unit 40 via the laser control processor 30 and store the received aerial image function A(λ) in the memory 61.

The convolution spectrum waveform obtained by convolution of the spectrum waveform of the pulse laser light and the aerial image function A(λ) of the exposure apparatus 4 may have a high correlation with the critical dimension of the exposure apparatus 4. The convolution spectrum waveform C0(λ) calculated using the estimation spectrum waveform T0(λ) as described above or the full width at half maximum thereof may be one of indices useful for laser control.

### 1.3 Problem of Comparative Example

However, it may take, for example, about 2600 μs to calculate deconvolution using the iterative method. When the repetition frequency of the pulse laser light is 6 kHz, since the repetition cycle is about 166 μs, it may be difficult to calculate the convolution spectrum waveform C0(λ) for each pulse of the pulse laser light.

### 2. Laser System La Calculating Convolution Spectrum Waveform C1(λ) Using Deconvolution Aerial Image Function D(λ)

### 2.1 Configuration

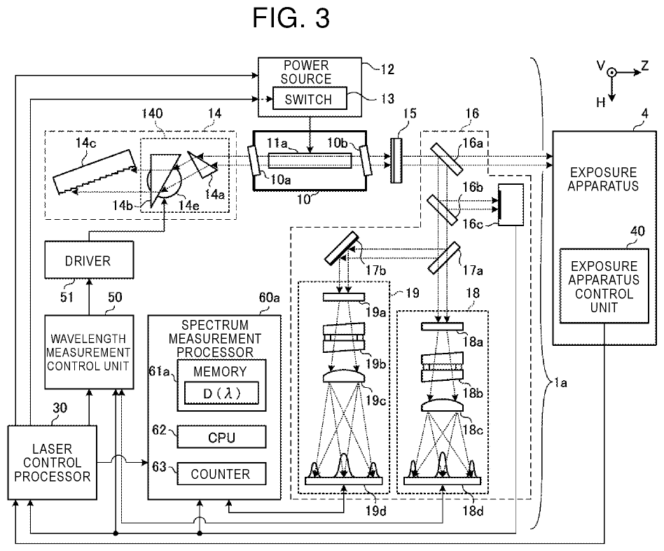

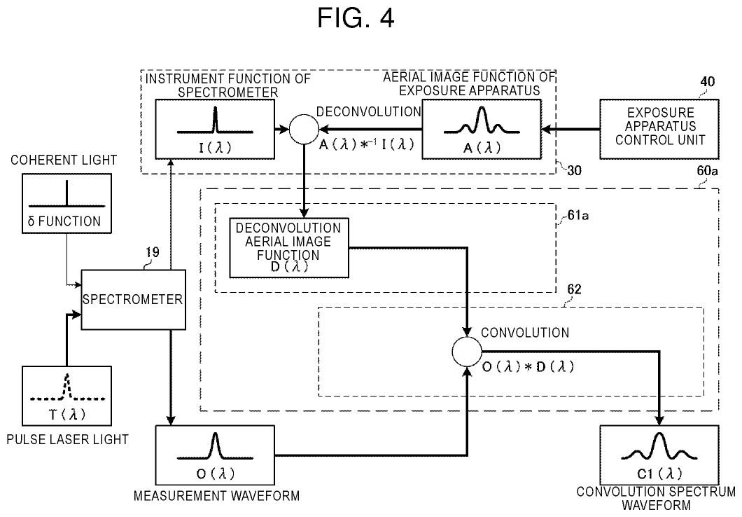

FIG. 3 schematically shows the configuration of a laser system 1a according to a first embodiment. FIG. 4 is a block diagram for explaining the function of the spectrum measurement processor 60a in the first embodiment.

The first embodiment differs from the comparative embodiment in that the memory 61a included in the spectrum measurement processor 60a stores a deconvolution aerial image function D(λ). The deconvolution aerial image function D(λ) is an example of the first intermediate function in the present disclosure. The memory 61a is an example of the storage medium in the present disclosure. The instrument function I(λ) of the spectrometer 19 and the aerial image function A(λ) of the exposure apparatus 4 may be stored in a memory (not shown) of the laser control processor 30.

### 2.2 Operation

In the first embodiment, the convolution spectrum waveform C1(λ) is calculated with the following method.

The laser control processor 30 calculates the deconvolution aerial image function D(λ) by deconvolution of the aerial image function A(λ) with the instrument function I(λ). The calculation of the deconvolution aerial image function D(λ) is performed, for example, when the laser control processor 30 receives the aerial image function A(λ) from the exposure apparatus control unit 40. The deconvolution aerial image function D(λ) is expressed by the following equation.

D(λ)=A(λ)*⁻¹I(λ)

The deconvolution aerial image function D(λ) can be calculated, for example, using the iterative method.

The spectrum measurement processor 60a receives the deconvolution aerial image function D(λ) from the laser control processor 30 to store it in the memory 61a in advance, and reads the deconvolution aerial image function D(λ) from the memory 61a when needed.

The CPU 62 included in the spectrum measurement processor 60a calculates the convolution spectrum waveform C1(λ) by convolution of the measurement waveform O(λ) and the deconvolution aerial image function D(λ) each time the measurement waveform O(λ) is acquired. The convolution spectrum waveform C1(λ) is expressed by the following equation.

C1(λ)=O(λ)*D(λ)

The CPU 62 may calculate a convolution spectrum line width that is the line width of the convolution spectrum waveform C1(λ). The convolution spectrum line width may be, for example, full width at half maximum.

### 2.3 Description of C0(λ) and C1(λ) being Equal to Each Other

The following shows that the convolution spectrum waveforms C0(λ), C1(λ) calculated in the comparative example and the first embodiment, respectively, are equal to each other.

As described above, the convolution spectrum waveform C0(λ) in the comparative example is given by the following equation.

C0(λ)=T0(λ)*A(λ)

This equation can be transformed by the convolution theorem as follows.

F(C0(λ))=F(T0(λ))×F(A(λ)) Equation 0.1

As described above, the estimation spectrum waveform T0(λ) is expressed as follows.

T0(λ)=F⁻¹(F(O(λ))/F(I(λ)))

When the Fourier transform is performed on both sides of this equation, it can be transformed as follows.

F(T0(λ))=F(O(λ))/F(I(λ)) Equation 0.2

From Equation 0.1 and Equation 0.2, F(C0(λ)) is expressed as follows.

F(C0(λ))=F(O(λ))×F(A(λ))/F(I(λ))

By performing the inverse Fourier transform on both sides of this equation, the convolution spectrum waveform C0(λ) in the comparative example is given by the following equation.

C0(λ)=F⁻¹(F(O(λ))×F(A(λ))/F(I(λ))) Equation 0.3

On the other hand, as described above, the convolution spectrum waveform C1(λ) in the first embodiment is given by the following equation.

C1(λ)=O(λ)*D(λ)

This equation can be transformed by the convolution theorem as follows.

F(C1(λ))=F(O(λ))×F(D(λ)) Equation 1.1

As described above, the deconvolution aerial image function D(λ) is expressed as follows.

D(λ)=A(λ)*⁻¹I(λ)

In this case, the aerial image function A(λ) of the exposure apparatus 4 is given by the following equation.

A(λ)=D(λ)*I(λ)

This equation can be transformed by the convolution theorem as follows:

F(A(λ))=F(D(λ))×F(I(λ))

By further transforming this equation, the Fourier transform of the deconvolution aerial image function D(λ) can be expressed as follows.

F(D(λ))=F(A(λ))/F(I(λ)) Equation 1.2

From Equation 1.1 and Equation 1.2, F(C1(λ)) is expressed as follows.

F(C1(λ))=F(O(λ))×F(A(λ))/F(I(λ))

By performing the inverse Fourier transform on both sides of this equation, the convolution spectrum waveform C1(λ) is given by the following equation.

C1(λ)=F⁻¹(F(O(λ))×F(A(λ))/F(I(λ))) Equation 1.3

From Equation 0.3 and Equation 1.3, the convolution spectrum waveforms C0(λ), C1(λ) calculated in the comparative example and the first embodiment, respectively, are equal to each other.

### 2.4 Effect

According to the first embodiment, the laser system 1a connectable to the exposure apparatus 4 includes the spectrometer 19 and the spectrum measurement processor 60a. The spectrometer 19 acquires the measurement waveform O(λ) from the interference pattern of the pulse laser light output from the laser system 1a. The spectrum measurement processor 60a is configured to calculate the convolution spectrum waveform C1(λ) using the measurement waveform O(λ) and the deconvolution aerial image function D(λ) as the first intermediate function obtained through the process of deconvolution of the aerial image function A(λ) of the exposure apparatus 4 with the instrument function I(λ) of the spectrometer 19. According to this, by using the deconvolution aerial image function D(λ), deconvolution of the measurement waveform O(λ) does not need to be performed, so that the convolution spectrum waveform C1(λ) can be calculated at high speed and the calculation frequency can be increased. There is a possibility that the convolution spectrum waveform C1(λ) can be calculated for each pulse of the pulse laser light.

According to the first embodiment, the laser system 1a further includes the memory 61a in which the deconvolution aerial image function D(λ) is stored. The deconvolution aerial image function D(λ) is the result of deconvolution of the aerial image function A(λ) with the instrument function I(λ). The spectrum measurement processor 60a reads the deconvolution aerial image function D(λ) from the memory 61a, and calculates the convolution spectrum waveform C1(λ) by convolution of the deconvolution aerial image function D(λ) and the measurement waveform O(λ). According to this, by preparing the deconvolution aerial image function D(λ) in advance, it is not necessary to perform deconvolution every time the measurement waveform O(λ) is acquired, so that the convolution spectrum waveform C1(λ) can be calculated at high speed.

According to the first embodiment, the laser control processor 30 performs deconvolution of the aerial image function A(λ) with the instrument function I(λ) to calculate the deconvolution aerial image function D(λ). The spectrum measurement processor 60a then stores the deconvolution aerial image function D(λ) in the memory 61a. According to this, since the deconvolution aerial image function D(λ) can be calculated in advance using, for example, the iterative method, it is possible to accurately calculate the convolution spectrum waveform C1(λ).

According to the first embodiment, the laser control processor 30 receives the aerial image function A(λ) from the exposure apparatus 4. According to this, it is possible to perform accurate laser control by reflecting the characteristics of each exposure apparatus 4.

According to the first embodiment, the spectrum measurement processor 60a further calculates the convolution spectrum line width, which is the line width of the convolution spectrum waveform C1(λ). According to this, it is possible to acquire an index useful for the laser control from the convolution spectrum waveform C1(λ).

In other respects, the first embodiment is similar to the comparative example. In the first embodiment, description has been provided on a case in which the laser system 1a outputs the pulse laser light, but the present disclosure is not limited thereto. The laser system 1a may output continuously oscillation laser light.

### 3. Laser System 1b Calculating Convolution Spectrum Waveform C2(λ) Using Fourier Transform F(D(λ)) of Deconvolution Aerial Image Function D(λ))

### 3.1 Configuration

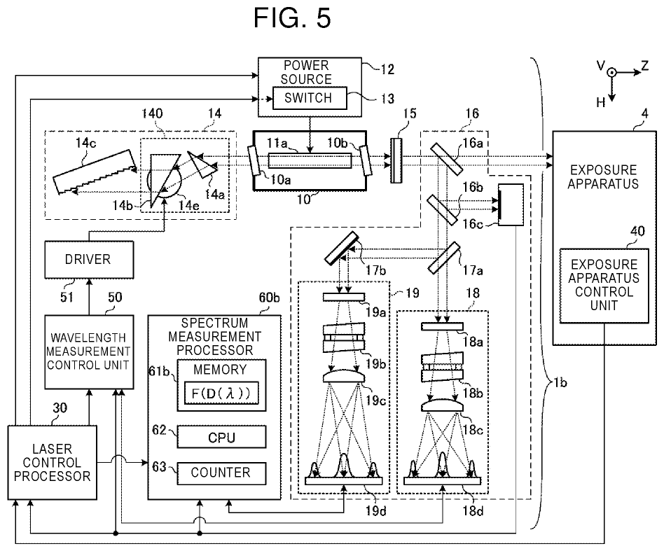

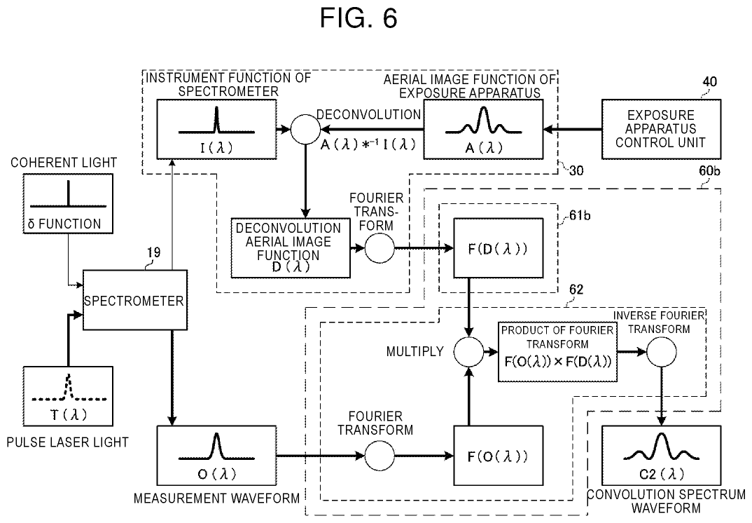

FIG. 5 schematically shows the configuration of a laser system 1b according to a second embodiment. FIG. 6 is a block diagram for explaining the function of a spectrum measurement processor 60b in the second embodiment.

The second embodiment differs from the first embodiment in that a memory 61b included in the spectrum measurement processor 60b stores the Fourier transform F(D(λ)) of the deconvolution aerial image function D(λ). The Fourier transform F(D(λ)) is an example of the first intermediate function in the present disclosure. The memory 61b is an example of the storage medium in the present disclosure.

### 3.2 Operation

In the second embodiment, a convolution spectrum waveform C2(λ) is calculated with the following method.

The laser control processor 30 calculates the deconvolution aerial image function D(λ) by deconvolution of the aerial image function A(λ) with the instrument function I(λ). The calculation of the deconvolution aerial image function D(λ) is performed, for example, using the iterative method. Further, the laser control processor 30 calculates the Fourier transform F(D(λ)) of the deconvolution aerial image function D(λ). The calculation of the Fourier transform F(D(λ)) may be performed by the fast Fourier transform. The calculation of the deconvolution aerial image function D(λ) and the Fourier transform F(D(λ)) thereof is performed, for example, when the laser control processor 30 receives the aerial image function A(λ) from the exposure apparatus control unit 40.

The spectrum measurement processor 60b receives the Fourier transform F(D(λ)) of the deconvolution aerial image function D(λ) from the laser control processor 30, stores it in the memory 61b in advance, and reads the Fourier transform F(D(λ)) from the memory 61b when needed.

Each time the measurement waveform O(λ) is acquired, the spectrum measurement processor 60b uses the Fourier transform F(D(λ)) and the measurement waveform O(λ) of the deconvolution aerial image function D(λ) to calculate the convolution spectrum waveform C2(λ) as follows.

The CPU 62 included in the spectrum measurement processor 60b calculates the Fourier transform F(O(λ)) of the measurement waveform O(λ). The Fourier transform F(O(λ)) can be calculated by the fast Fourier transform. The Fourier transform F(O(λ)) corresponds to the second intermediate function in the present disclosure.

Next, the CPU 62 calculates the product F(O(λ))×F(D(λ)) of the Fourier transform by multiplying the Fourier transform F(O(λ)) of the measurement waveform O(λ) by the Fourier transform F(D(λ)) of the deconvolution aerial image function D(λ).

Next, the CPU 62 calculates the convolution spectrum waveform C2(λ) by performing the inverse Fourier transform on the product F(O(λ))×F(D(λ)) of the Fourier transform. The inverse Fourier transform can be calculated by the fast inverse Fourier transform. The convolution spectrum waveform C2(λ) is expressed by the following equation.

C2(λ)=F⁻¹(F(O(λ))×F(D(λ)))

The CPU 62 may calculate a convolution spectrum line width that is the line width of the convolution spectrum waveform C2(λ). The convolution spectrum line width may be, for example, full width at half maximum.

### 3.3 Description of C2(λ) being Equal to Each of C0(λ) and C1(λ)

The following shows that the convolution spectrum waveform C2(λ) calculated in the second embodiment is equal to each of the convolution spectrum waveforms C0(λ) and C1(λ) calculated in the comparative example and the first embodiment, respectively.

As described above, the convolution spectrum waveform C2(λ) in the second embodiment is given by the following equation.

C2(λ)=F⁻¹(F(O(λ))×F(D(λ))) Equation 2.1

On the other hand, Equation 1.2 described above holds as well in the second embodiment.

F(D(λ))=F(A(λ))/F(I(λ)) Equation 1.2

From Equation 2.1 and Equation 1.2, the convolution spectrum waveform C2(λ) is given by the following equation.

C2(λ)=F⁻¹(F(O(λ))×F(A(λ))/F(I(λ))) Equation 2.3

From Equation 0.3, Equation 1.3, and Equation 2.3, the convolution spectrum waveform C2(λ) calculated in the second embodiment is equal to each of C0(λ) and C1(λ).

### 3.4 Effect

According to the second embodiment, the laser system 1b includes the memory 61b in which the Fourier transform F(D(λ)) of the deconvolution aerial image function D(λ) is stored as the first intermediate function. The Fourier transform F(D(λ)) is a function obtained by performing the Fourier transform on the result of deconvolution of the aerial image function A(λ) with the instrument function I(λ). The spectrum measurement processor 60b reads the Fourier transform F(D(λ)) from the memory 61b and calculates the Fourier transform F(O(λ)) of the measurement waveform O(λ). The spectrum measurement processor 60b calculates the product F(O(λ))×F(D(λ)) of the Fourier transform F(O(λ)) and the Fourier transform F(D(λ)), and calculates the convolution spectrum waveform C2(λ) by performing the inverse Fourier transform on the product F(O(λ))×F(D(λ)). According to this, the convolution spectrum waveform C2(λ) can be calculated at high speed by using the Fourier transform and the inverse Fourier transform instead of the convolution O(λ)*D(λ) in the first embodiment.

According to the second embodiment, the laser control processor 30 performs deconvolution of the aerial image function A(λ) with the instrument function I(λ) to calculate the deconvolution aerial image function D(λ), and further calculates the Fourier transform F(D(λ)) of the deconvolution aerial image function D(λ). Then, the spectrum measurement processor 60b stores the Fourier transform F(D(λ)) in the memory 61b. According to this, since the deconvolution aerial image function D(λ) can be calculated in advance using, for example, the iterative method, it is possible to accurately calculate the convolution spectrum waveform C2(λ).

According to the second embodiment, the spectrum measurement processor 60b performs the Fourier transform on the measurement waveform O(λ) using the fast Fourier transform and performs the inverse Fourier transform on the product F(O(λ))×F(D(λ)) using the fast inverse Fourier transform. According to this, it is possible to calculate the convolution spectrum waveform C2(λ) at high speed. In other respects, the second embodiment is similar to the first embodiment.

### 4. Laser System 1c Including Adjustment Mechanism of Spectrum Line Width by Wavefront Adjustment

### 4.1 Configuration

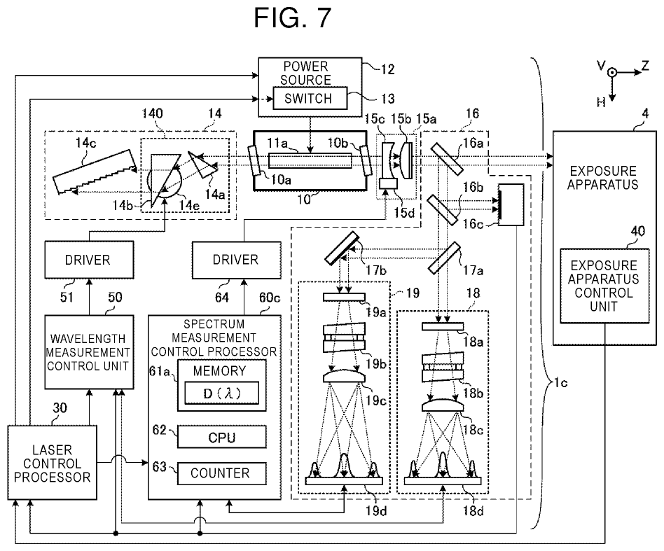

FIG. 7 schematically shows the configuration of a laser system 1c according to a third embodiment. The laser system 1c includes a wavefront adjuster 15a that reflects a part of the pulse laser light instead of the output coupling mirror 15. The wavefront adjuster 15a is an example of the adjustment mechanism in the present disclosure. The laser system 1c includes a spectrum measurement control processor 60c instead of the spectrum measurement processor 60a. The spectrum measurement control processor 60c is connected to a driver 64 that drives the wavefront adjuster 15a.

The wavefront adjuster 15a includes a cylindrical plano-convex lens 15b, a cylindrical plano-concave lens 15c, and a linear stage 15d. The cylindrical plano-concave lens 15c is located between the laser chamber 10 and the cylindrical plano-convex lens 15b. The cylindrical plano-convex lens 15b and the cylindrical plano-concave lens 15c are arranged such that the convex surface of the cylindrical plano-convex lens 15b and the concave surface of the cylindrical plano-concave lens 15c face each other. The convex surface of the cylindrical plano-convex lens 15b and the concave surface of the cylindrical plano-concave lens 15c each have a focal axis parallel to the direction of the V-axis. The planar surface of the cylindrical plano-convex lens 15b opposite to the convex surface is coated with a partial reflection film. The wavefront adjuster 15a and the line narrowing module 14 configure a laser resonator.

### 4.2 Operation

The linear stage 15d moves the cylindrical plano-concave lens 15c along the optical path between the laser chamber 10 and the cylindrical plano-convex lens 15b in accordance with a drive signal output from the driver 64. Thus, the wavefront of the light from the wavefront adjuster 15a to the line narrowing module 14 changes. As the wavefront changes, the spectrum line width of the wavelength selected by the line narrowing module 14 changes and the convolution spectrum line width changes.

The spectrum measurement control processor 60c receives a target value of the convolution spectrum line width from the exposure apparatus control unit 40 via the laser control processor 30. Further, the spectrum measurement control processor 60c calculates the convolution spectrum line width using the measurement waveform O(λ). The spectrum measurement control processor 60c transmits a control signal to the driver 64 based on the target value of the convolution spectrum line width and the calculated convolution spectrum line width to control the wavefront adjuster 15a, thereby performing feedback control of the convolution spectrum line width.

In other respects, the third embodiment is similar to the first embodiment. Alternatively, in the third embodiment, the convolution spectrum waveform C2(λ) may be calculated using the Fourier transform F(D(λ)) of the deconvolution aerial image function D(λ) as in the second embodiment. Further, in the third embodiment, the following variations may be employed.

### 4.3 Variations of Wavefront Adjuster

### 4.3.1 Wavefront Adjuster 15e Arranged Between Output Coupling Mirror 15 and Laser Chamber 10

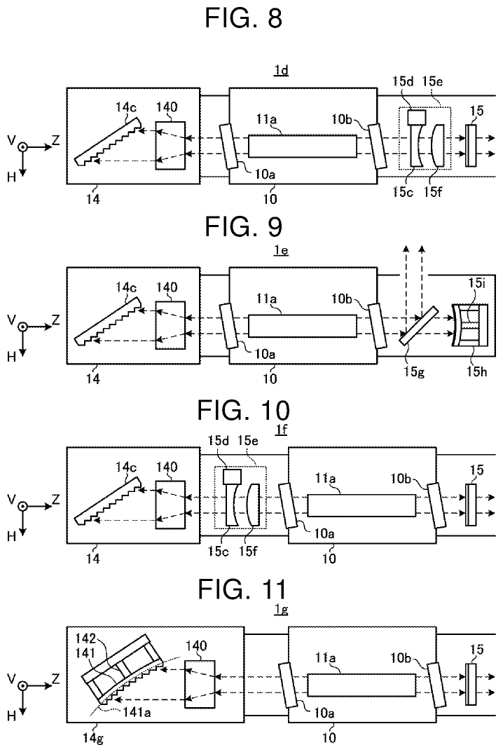

FIG. 8 shows a laser system 1d with a first variation of the wavefront adjuster. FIG. 8 corresponds to a view of the laser system 1d viewed from the same direction as FIG. 7, but some components are simplified or omitted.

In FIG. 8, a wavefront adjuster 15e is arranged between the output coupling mirror 15 and the laser chamber 10. The wavefront adjuster 15e is an example of the adjustment mechanism in the present disclosure. The wavefront adjuster 15e includes, instead of the cylindrical plano-convex lens 15b, a cylindrical plano-convex lens 15f that does not include a partial reflection film. The cylindrical plano-convex lens 15f transmits the light output from the laser chamber 10 with high transmittance and causes the light to be incident on the output coupling mirror 15. The output coupling mirror 15 and the line narrowing module 14 configure a laser resonator.

By moving the cylindrical plano-concave lens 15c included in the wavefront adjuster 15e, the wavefront of the light from the wavefront adjuster 15e to the line narrowing module 14 changes. Therefore, the spectrum line width of the wavelength selected by the line narrowing module 14 changes and the convolution spectrum line width changes.

### 4.3.2 Wavefront Adjuster 15h Configured of Deformable Mirror

FIG. 9 shows a laser system 1e with a second variation of the wavefront adjuster. FIG. 9 corresponds to a view of the laser system 1e viewed from the same direction as FIG. 7, but some components are simplified or omitted.

In FIG. 9, the wavefront adjuster 15h is configured of a deformable mirror with high reflectance. The wavefront adjuster 15h is an example of the adjustment mechanism in the present disclosure. The deformable mirror is a mirror capable of changing the curvature of the reflection surface due to expansion and contraction of an expansion-contraction portion 15i. The reflection surface of the deformable mirror is a cylindrical surface, and the focal axis of the reflection surface is parallel to the V axis. The wavefront adjuster 15h and the line narrowing module 14 configure a laser resonator.

By changing the radius of curvature of the reflection surface of the deformable mirror, the wavefront of the light from the wavefront adjuster 15h to the line narrowing module 14 changes. Therefore, the spectrum line width of the wavelength selected by the line narrowing module 14 changes and the convolution spectrum line width changes.

A beam splitter 15g as an output coupling mirror is arranged on the optical path between the wavefront adjuster 15h and the laser chamber 10. The beam splitter 15g transmits part of the light output from the window 10b, thereby allowing the light to reciprocate between the wavefront adjuster 15h and the line narrowing module 14. The beam splitter 15g reflects the other part of the light output from the window 10b and outputs the reflected light toward the exposure apparatus 4 as the pulse laser light.

### 4.3.3 Wavefront Adjuster 15e Arranged Between Line Narrowing Module 14 and Laser Chamber 10

FIG. 10 shows a laser system 1f with a third variation of the wavefront adjuster. FIG. 10 corresponds to a view of the laser system 1f viewed from the same direction as FIG. 7, but some components are simplified or omitted.

In FIG. 10, the wavefront adjuster 15e is arranged between the line narrowing module 14 and the laser chamber 10. The configuration of the wavefront adjuster 15e is similar to that described with reference to FIG. 8. The output coupling mirror 15 and the line narrowing module 14 configure a laser resonator.

### 4.3.4 Grating 141 Capable of Changing Shape Thereof

FIG. 11 shows a laser system 1g with a fourth variation of the wavefront adjuster. FIG. 11 corresponds to a view of the laser system 1g viewed from the same direction as FIG. 7, but some components are simplified or omitted.

The laser system 1g includes a line narrowing module 14g, and the line narrowing module 14g includes a grating 141. The grating 141 is an example of the adjustment mechanism in the present disclosure. The curvature of an envelope surface 141a of grooves of the grating 141 is to be changeable by the expansion and contraction of an expansion-contraction portion 142. The envelope surface 141a is a cylindrical surface, and the focal axis of the envelope surface 141a is parallel to the V axis. The output coupling mirror 15 and the line narrowing module 14g configure a laser resonator.

By changing the curvature of the envelope surface 141a, the relationship between the envelope surface 141a and the wavefront of the pulse laser light is changed. Therefore, the spectrum line width of the wavelength selected by the line narrowing module 14g changes and the convolution spectrum line width changes.

### 4.4 Effect

According to the third embodiment, the spectrum measurement control processor 60c receives the target value of the convolution spectrum line width from the exposure apparatus 4 via the laser control processor 30. According to this, it is possible to perform accurate laser control in accordance with a request from the exposure apparatus 4.

According to the third embodiment, each of the laser systems 1c to 1g includes the adjustment mechanism, and the spectrum measurement control processor 60c controls the adjustment mechanism based on the convolution spectrum line width. According to this, laser control can be performed using an effective index obtained from the convolution spectrum waveform C1(λ).

According to the third embodiment, each of the laser systems 1c to 1g includes the laser resonator, and the adjustment mechanism includes the wavefront adjuster 15a, 15e, 15h, or the grating 141 arranged on the optical path of the laser resonator. According to this, the convolution spectrum line width can be controlled by adjusting the wavefront of the light in the laser resonator.

### 5. Laser System 1h Including Adjustment Mechanism of Spectrum Line Width by Beam Width Adjustment

### 5.1 Configuration

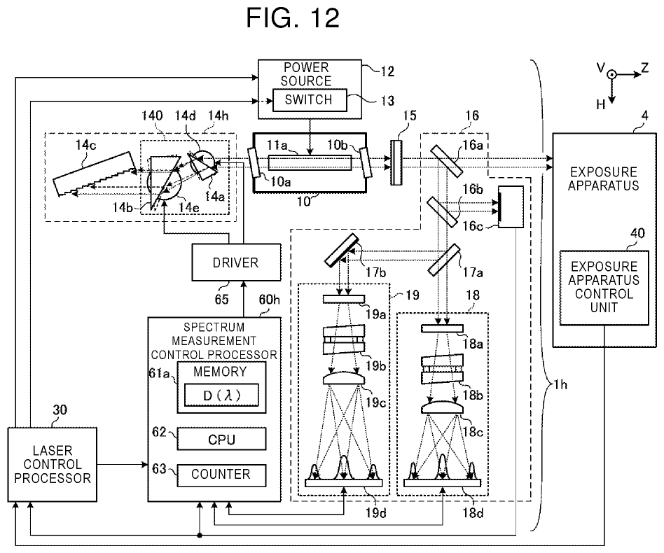

FIG. 12 schematically shows the configuration of a laser system 1h according to a fourth embodiment. The laser system 1h includes, instead of the line narrowing module 14, a line narrowing module 14h capable of adjusting the beam width of light incident on the grating 14c. The laser system 1h includes a spectrum measurement control processor 60h instead of the wavelength measurement control unit 50 and the spectrum measurement processor 60a. The spectrum measurement control processor 60h is connected to a driver 65 that drives the line narrowing module 14h.

In the line narrowing module 14h, not only the prism 14b is supported by the rotation stage 14e, but also the prism 14a is supported by the rotation stage 14d. The rotation stages 14d, 14e are examples of the adjustment mechanism in the present disclosure. The rotation stages 14d, 14e are configured to rotate the prisms 14a, 14b about an axis parallel to the V axis, respectively, in accordance with a drive signal output from the driver 65.

### 5.2 Operation

When the prisms 14a, 14b are rotated in opposite directions to each other by the rotation stages 14d, 14e, the incident angle of light on the grating 14c does not change significantly, but the beam width of the light incident on the grating 14c changes. Therefore, although the center wavelength of the pulse laser light does not change significantly, the spectrum line width changes and the convolution spectrum line width changes.

By adjusting the rotation angles of the prisms 14a, 14b, it is possible to change not only the beam width of the light incident on the grating 14c but also the incident angle of the light on the grating 14c. This makes it possible to change not only the spectrum line width and the convolution spectrum line width of the pulse laser light but also the center wavelength.

The spectrum measurement control processor 60h receives setting data of the target wavelength from the exposure apparatus control unit 40 via the laser control processor 30. Further, the spectrum measurement control processor 60h calculates the center wavelength of the pulse laser light using the waveform data of the interference fringes output from the wavelength detector 18. The spectrum measurement control processor 60h outputs a control signal to the driver 65 based on the target wavelength and the calculated center wavelength, thereby performing feedback control of the center wavelength of the pulse laser light.

The spectrum measurement control processor 60h receives the target value of the convolution spectrum line width from the exposure apparatus control unit 40 via the laser control processor 30. Further, the spectrum measurement control processor 60h calculates the convolution spectrum line width using the measurement waveform O(λ). The spectrum measurement control processor 60h outputs a control signal to the driver 65 based on the target value of the convolution spectrum line width and the calculated convolution spectrum line width, thereby performing feedback control of the convolution spectrum line width.

In other respects, the fourth embodiment is similar to the first embodiment. Alternatively, in the fourth embodiment, the adjustment mechanism of the spectrum line width similar to that in the third embodiment may be added, and the convolution spectrum line width may be controlled by both the wavefront adjustment and the beam width adjustment. Alternatively, in the fourth embodiment, the convolution spectrum waveform C2(λ) may be calculated using the Fourier transform F(D(λ)) of the deconvolution aerial image function D(λ) as in the second embodiment. Further, in the fourth embodiment, the following variations may be employed.

### 5.3 Adjustment Mechanism of Spectrum Line Width for Changing Beam Width by Replacing Prisms 144, 147

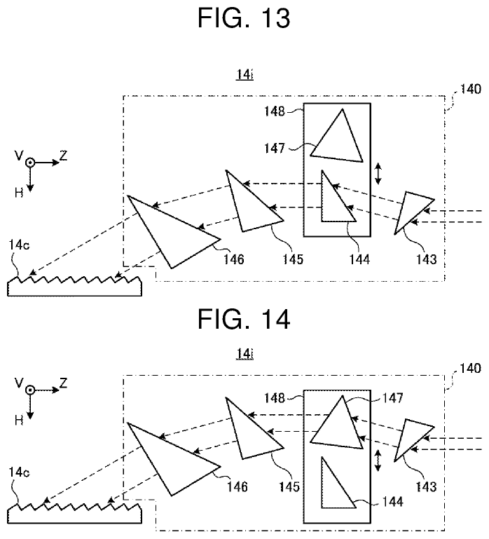

FIGS. 13 and 14 show a line narrowing module 14i including a variation of the mechanism for adjusting the beam width. The line narrowing module 14i includes prisms 143 to 147.

As shown in FIG. 13, the prisms 143, 144, 145, 146 are arranged in this order from the laser chamber 10 side toward the grating 14c. The prism 144 changes both the beam width and the travel direction of the light incident from the prism 143 and causes the light to be incident on the prism 145.

The prism 144 and the prism 147 are arranged on a uniaxial stage 148 and are movable by the uniaxial stage 148. The uniaxial stage 148 is an example of the adjustment mechanism in the present disclosure. As shown in FIG. 14, the prism 147 can be arranged on the optical path of the laser resonator instead of the prism 144. Similarly to the prism 144, the prism 147 changes the travel direction of the light incident from the prism 143 and causes the light to be incident on the prism 145. However, the prism 147 is different from the prism 144 in the expansion rate of the beam width. For example, the prism 147 may cause the light incident from the prism 143 to be incident on the prism 145 without expanding the beam width of the light.

By replacing the prism 144 with the prism 147, the incident angle of the light incident on the grating 14c from the prism 146 does not change significantly, but the beam width of the light incident on the grating 14c from the prism 146 changes. Therefore, before and after the replacement of the prism 144 with the prism 147, the center wavelength of the pulse laser light does not change significantly, but the spectrum line width changes and the convolution spectrum line width changes.

In the configurations of FIGS. 13 and 14, a rotation stage (not shown) for rotating the prism 145 or 146 about an axis parallel to the V axis may be further provided so that the center wavelength of the pulse laser light can be adjusted.

### 5.4 Effect

According to the fourth embodiment, the laser system 1h includes the line narrowing module 14h including the grating 14c and the plurality of prisms 14a, 14b. The rotation stages 14d, 14e as the adjustment mechanisms change the beam width of the light incident on the grating 14c by changing the posture of the plurality of prisms 14a, 14b. Alternatively, the laser system 1h includes the line narrowing module 14i including the grating 14c and the plurality of prisms 144, 147. The uniaxial stage 148 as the adjustment mechanism changes the beam width of the light incident on the grating 14c by changing the positions of the plurality of prisms 144, 147. According to this, the convolution spectrum line width can be controlled by changing the beam width of the light incident on the grating 14c.

### 6. Laser System 1j Including Adjustment Mechanism of Spectrum Line Width by Fluorine Partial Pressure

### 6.1 Configuration

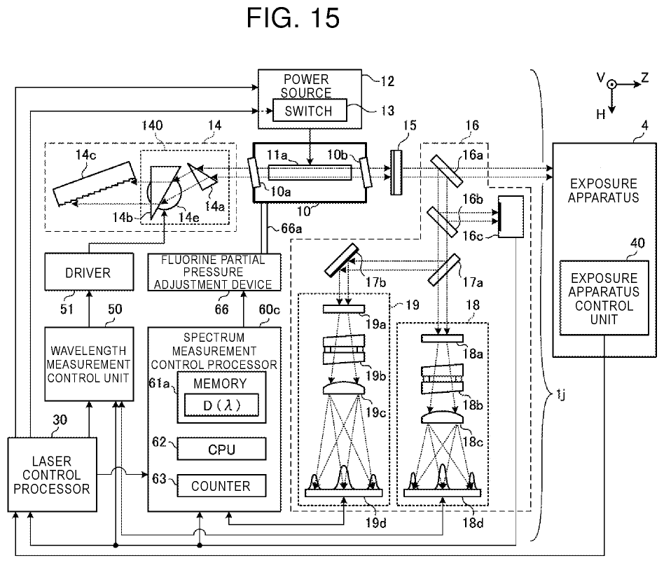

FIG. 15 schematically shows the configuration of a laser system 1j according to a fifth embodiment. The laser system 1j includes a fluorine partial pressure adjustment device 66. The fluorine partial pressure adjustment device 66 is an example of the adjustment mechanism in the present disclosure. The fluorine partial pressure adjustment device 66 includes a fluorine-containing gas supply source (not shown), a valve, and an exhaust device, and is connected to the laser chamber 10 via a gas pipe 66a. The fluorine-containing gas supply source contains a fluorine-containing laser gas having a higher fluorine concentration than the laser gas in the laser chamber 10. The spectrum measurement control processor 60c is connected to the fluorine partial pressure adjustment device 66.

### 6.2 Operation

The fluorine partial pressure adjustment device 66 adjusts the fluorine partial pressure in the laser chamber 10 in accordance with a control signal output from the spectrum measurement control processor 60c. The spectrum line width changes in accordance with the fluorine partial pressure, and the convolution spectrum line width changes. For example, when the fluorine-containing laser gas is supplied into the laser chamber 10, the fluorine partial pressure increases and the convolution spectrum line width increases. When the gas in the laser chamber 10 is partially exhausted, the fluorine partial pressure decreases and the convolution spectrum line width decreases.

The spectrum measurement control processor 60c receives the target value of the convolution spectrum line width from the exposure apparatus control unit 40 via the laser control processor 30. Further, the spectrum measurement control processor 60c calculates the convolution spectrum line width using the measurement waveform O(λ). The spectrum measurement control processor 60c transmits a control signal to the fluorine partial pressure adjustment device 66 based on the target value of the convolution spectrum line width and the calculated convolution spectrum line width, thereby performing feedback control of the convolution spectrum line width.

In other respects, the fifth embodiment is similar to the first embodiment. Alternatively, in the fifth embodiment, the adjustment mechanism of the spectrum line width similar to that in the third or fourth embodiment may be added, and the convolution spectrum line width may be controlled by both the wavefront adjustment or the beam width adjustment and the fluorine partial pressure. Alternatively, in the fifth embodiment, the convolution spectrum waveform C2(λ) may be calculated using the Fourier transform F(D(λ)) of the deconvolution aerial image function D(λ) as in the second embodiment.

### 6.3 Effect

According to the fifth embodiment, the laser system 1j includes the laser chamber 10 containing a fluorine-containing laser gas. The fluorine partial pressure adjustment device 66 as the adjustment mechanism adjusts the fluorine partial pressure in the laser chamber 10. According to this, the convolution spectrum line width can be controlled by adjusting the fluorine partial pressure in the laser chamber 10.

### 7. Laser System 1k Including Master Oscillator MO and Power Oscillator PO

### 7.1 Configuration

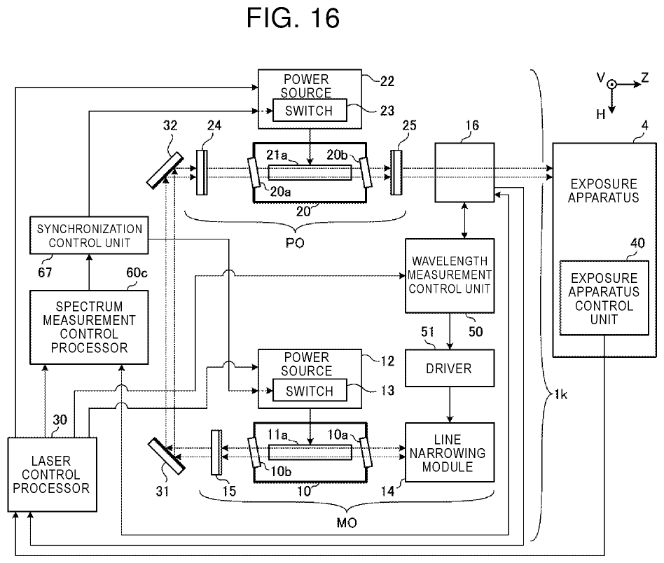

FIG. 16 schematically shows the configuration of a laser system 1k according to a six embodiment. The laser system 1k includes a master oscillator MO, a power oscillator PO, a monitor module 16, a laser control processor 30, high reflection mirrors 31, 32, a wavelength measurement control unit 50, a driver 51, a spectrum measurement control processor 60c, and a synchronization control unit 67. The synchronization control unit 67 is an example of the adjustment mechanism in the present disclosure. The configurations of the laser control processor 30, the wavelength measurement control unit 50, the driver 51, and the spectrum measurement control processor 60c are similar to the corresponding configurations in the third embodiment.

The master oscillator MO includes the laser chamber 10, the discharge electrode 11a, the power source 12, the line narrowing module 14, and the output coupling mirror 15. The configurations are similar to the corresponding configurations in the third embodiment.

The high reflection mirrors 31, 32 are arranged on the optical path of the pulse laser light output from the master oscillator MO. Each of the high reflection mirrors 31, 32 is configured such that the position and posture thereof can be changed by an actuator (not shown). The high reflection mirrors 31, 32 configure a beam steering unit for adjusting an incident position and an incident direction of the pulse laser light on the power oscillator PO.

The power oscillator PO is arranged on the optical path of the pulse laser light that has passed through the beam steering unit. The power oscillator PO includes a laser chamber 20, a discharge electrode 21a, a power source 22, a rear mirror 24, and an output coupling mirror 25.

The rear mirror 24 is made of a material that transmits the pulse laser light, and one surface thereof is coated with a partial reflection film. The reflectance of the rear mirror 24 is set higher than the reflectance of the output coupling mirror 25. The rear mirror 24 and the output coupling mirror 25 configure a laser resonator. The laser chamber 20 is arranged on the optical path of the laser resonator. Windows 20a, 20b are arranged at both ends of the laser chamber 20. The discharge electrode 21a and a discharge electrode (not shown) paired therewith are arranged inside the laser chamber 20. The power source 22 includes a switch 23 and is connected to the discharge electrode 21a and a charger (not shown).

In other respects, the above-described components of the power oscillator PO are similar to the corresponding components of the master oscillator MO.

The monitor module 16 is arranged on the optical path of the pulse laser light between the output coupling mirror 25 and the exposure apparatus 4. The configuration of the monitor module 16 is similar to the corresponding configuration in the third embodiment. The synchronization control unit 67 is connected to the switches 13, 23.

### 7.2 Operation

### 7.2.1 Laser Control Processor 30

The laser control processor 30 sets a first target pulse energy of the pulse laser light output from the master oscillator MO. The laser control processor 30 further receives setting data of a second target pulse energy of the pulse laser light output from the power oscillator PO from the exposure apparatus control unit 40.

The laser control processor 30 transmits setting data of the application voltage to the power sources 12, 22, respectively, based on the first and second target pulse energies. The laser control processor 30 transmits a trigger signal received from the exposure apparatus control unit 40 to the spectrum measurement control processor 60c. The spectrum measurement control processor 60c transmits a trigger signal to the synchronization control unit 67, and the synchronization control unit 67 transmits, based on the trigger signal, first and second oscillation trigger signals to the switches 13, 23, respectively.

### 7.2.2 Master Oscillator MO

The operation of the master oscillator MO is similar to the operation of the laser system 1c in the third embodiment.

### 7.2.3 Power Oscillator PO

The switch 23 included in the power source 22 is turned on when the second oscillation trigger signal is received from the synchronization control unit 67. When the switch 23 is turned on, the power source 22 generates a pulse high voltage from the electric energy charged in the charger (not shown), and applies the high voltage to the discharge electrode 21a.

The delay time of the second oscillation trigger signal to the switch 23 with respect to the first oscillation trigger signal to the switch 13 is set so that the timing at which discharge occurs in the laser chamber 20 is synchronized with the timing at which the pulse laser light output from the master oscillator MO enters the laser chamber 20.

The pulse laser light reciprocates between the rear mirror 24 and the output coupling mirror 25, and is amplified each time it passes through the discharge space in the laser chamber 20. The amplified pulse laser light is output from the output coupling mirror 25.

### 7.2.4 Spectrum Measurement Control Processor 60c

The spectrum measurement control processor 60c receives the target value of the convolution spectrum line width from the exposure apparatus control unit 40 via the laser control processor 30. Further, the spectrum measurement control processor 60c calculates the convolution spectrum line width using the measurement waveform O(λ). The spectrum measurement control processor 60c sets a delay time of the second oscillation trigger signal with respect to the first oscillation trigger signal based on the target value of the convolution spectrum line width and the calculated convolution spectrum line width, and transmits a setting signal of the delay time to the synchronization control unit 67. The synchronization control unit 67 transmits the first and second oscillation trigger signals to the switches 13, 23, respectively, based on the setting signal of the delay time and the trigger signal received from the spectrum measurement control processor 60c. Thus, feedback control is performed on the convolution spectrum line width.

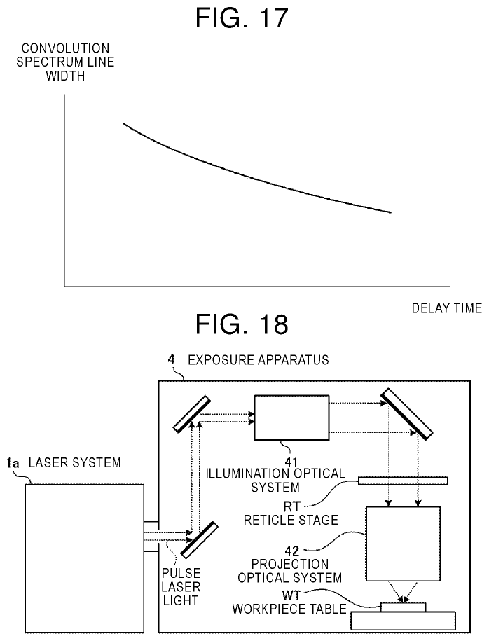

FIG. 17 is a graph showing the relationship between the delay time of the second oscillation trigger signal to the power oscillator PO with respect to the first oscillation trigger signal to the master oscillator MO and the convolution spectrum line width of the pulse laser light output from the power oscillator PO. The spectrum line width changes in accordance with the delay time, and the convolution spectrum line width changes. As the delay time becomes shorter, the convolution spectrum line width becomes larger, and as the delay time becomes longer, the convolution spectrum line width becomes smaller. Therefore, the convolution spectrum line width can be controlled by the delay time set by the spectrum measurement control processor 60c.

In other respects, the sixth embodiment is similar to the first embodiment. Alternatively, in the sixth embodiment, the adjustment mechanism of the spectrum line width similar to that in the third, fourth, or fifth embodiment may be added, and the convolution spectrum line width may be controlled by both the wavefront adjustment, the beam width adjustment, or fluorine partial pressure and the delay time of the second oscillation trigger signal with respect to the first oscillation trigger signal. Alternatively, in the sixth embodiment, a laser device using a solid-state laser may be adopted as the master oscillator MO instead of the gas laser device, and the convolution spectrum line width may be controlled by the delay time of the second oscillation trigger signal with respect to the first oscillation trigger signal. Alternatively, in the sixth embodiment, the convolution spectrum waveform C2(λ) may be calculated using the Fourier transform F(D(λ)) of the deconvolution aerial image function D(λ) as in the second embodiment.

### 7.3 Effect

According to the sixth embodiment, the laser system 1k includes the master oscillator MO and the power oscillator PO. The synchronization control unit 67 as the adjustment mechanism adjusts the delay time of the second oscillation trigger signal output to the power oscillator PO with respect to the first oscillation trigger signal output to the master oscillator MO. According to this configuration, the convolution spectrum line width can be controlled by adjusting the delay time of the second oscillation trigger signal with respect to the first oscillation trigger signal.

### 8. Others

FIG. 18 schematically shows the configuration of the exposure apparatus 4 connected to the laser system 1a. The laser system 1a generates pulse laser light and outputs the pulse laser light to the exposure apparatus 4. In FIG. 18, the exposure apparatus 4 includes an illumination optical system 41 and a projection optical system 42. The illumination optical system 41 illuminates a reticle pattern of a reticle (not shown) arranged on a reticle stage RT with the pulse laser light incident from the laser system 1a. The projection optical system 42 causes the pulse laser light transmitted through the reticle to be imaged as being reduced and projected on a workpiece (not shown) arranged on a workpiece table WT. The workpiece is a photosensitive substrate such as a semiconductor wafer on which photoresist is applied. The exposure apparatus 4 synchronously translates the reticle stage RT and the workpiece table WT to expose the workpiece to the pulse laser light reflecting the reticle pattern. After the reticle pattern is transferred onto the semiconductor wafer by the exposure process described above, an electronic device can be manufactured through a plurality of processes. Any of the laser systems 1b to 1h, 1j, and 1k may be used instead of the laser system 1a.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A laser system connectable to an exposure apparatus, comprising:
a spectrometer configured to acquire a measurement waveform from an interference pattern of laser light output from the laser system; and
a processor configured to calculate a convolution spectrum waveform using the measurement waveform and a first intermediate function obtained through a process of deconvolution of an aerial image function of the exposure apparatus with an instrument function of the spectrometer.

2. The laser system according to claim 1, further comprising a storage medium in which the first intermediate function is stored,
wherein the first intermediate function is a result of deconvolution of the aerial image function with the instrument function, and
the processor reads the first intermediate function from the storage medium and calculates the convolution spectrum waveform by convolution of the first intermediate function and the measurement waveform.

3. The laser system according to claim 2,
wherein the processor calculates the result as the first intermediate function and stores the first intermediate function in the storage medium.

4. The laser system according to claim 1, further comprising a storage medium in which the first intermediate function is stored,
wherein the first intermediate function is a function obtained by performing Fourier transform on a result of deconvolution of the aerial image function with the instrument function, and
the processor reads the first intermediate function from the storage medium, calculates a second intermediate function obtained by performing Fourier transform on the measurement waveform, calculates a product of the first intermediate function and the second intermediate function, and calculates a convolution spectrum waveform by performing inverse Fourier transform on the product.

5. The laser system according to claim 4,
wherein the processor calculates the result, calculates the first intermediate function by performing Fourier transform on the result, and stores the first intermediate function in the storage medium.

6. The laser system according to claim 4,
wherein the processor performs Fourier transform on the measurement waveform using fast Fourier transform and performs inverse Fourier transform on the product using fast inverse Fourier transform.

7. The laser system according to claim 1,
wherein the processor receives the aerial image function from the exposure apparatus.

8. The laser system according to claim 1,
wherein the processor further calculates a line width of the convolution spectrum waveform.

9. The laser system according to claim 8,
wherein the processor receives a target value of the line width from the exposure apparatus.

10. The laser system according to claim 8, further comprising an adjustment mechanism,
wherein the processor controls the adjustment mechanism based on the line width.

11. The laser system according to claim 10, further comprising a laser resonator,
wherein the adjustment mechanism includes a wavefront adjuster arranged on an optical path of the laser resonator.

12. The laser system according to claim 10, further comprising a line narrowing module including a grating and a plurality of prisms,
wherein the adjustment mechanism changes a beam width of light incident on the grating by changing a posture or a position of the plurality of prisms.

13. The laser system according to claim 10, further comprising a laser chamber which accommodates laser gas containing fluorine,
wherein the adjustment mechanism includes a fluorine partial pressure adjustment device which adjusts fluorine partial pressure in the laser chamber.

14. The laser system according to claim 10, further comprising a master oscillator and a power oscillator,
wherein the adjustment mechanism adjusts a delay time of a second oscillation trigger signal output to the power oscillator with respect to a first oscillation trigger signal output to the master oscillator.

15. A spectrum waveform calculation method, comprising:
causing laser light output from a laser system connectable to an exposure apparatus to be incident on a spectrometer;
acquiring a measurement waveform from an interference pattern of the laser light by the spectrometer; and
calculating a convolution spectrum waveform using the measurement waveform and a first intermediate function obtained through a process of deconvolution of an aerial image function of the exposure apparatus with an instrument function of the spectrometer.

16. The spectrum waveform calculation method according to claim 15,
wherein the first intermediate function is read from a storage medium in which the first intermediate function being a result of deconvolution of the aerial image function with the instrument function is stored, and
the convolution spectrum waveform is calculated by convolution of the first intermediate function and the measurement waveform.

17. The spectrum waveform calculation method according to claim 15,
wherein the first intermediate function is read from a storage medium in which the first intermediate function obtained by performing Fourier transform on a result of deconvolution of the aerial image function with the instrument function,
a second intermediate function obtained by performing Fourier transform on the measurement waveform is calculated,
a product of the first intermediate function and the second intermediate function is calculated, and
the convolution spectrum waveform is calculated by performing inverse Fourier transform on the product.

18. An electronic device manufacturing method, comprising:
generating laser light using a laser system;
outputting the laser light to an exposure apparatus; and
exposing a photosensitive substrate to the laser light in the exposure apparatus to manufacture an electronic device,
the laser system including:
a spectrometer configured to acquire a measurement waveform from an interference pattern of the laser light output from the laser system connectable to the exposure apparatus; and
a processor configured to calculate a convolution spectrum waveform using the measurement waveform and a first intermediate function obtained through a process of deconvolution of an aerial image function of the exposure apparatus with an instrument function of the spectrometer.

19. The electronic device manufacturing method according to claim 18,
wherein the processor reads the first intermediate function from a storage medium in which the first intermediate function being a result of deconvolution of the aerial image function with the instrument function is stored, and calculates the convolution spectrum waveform by convolution of the first intermediate function and the measurement waveform.

20. The electronic device manufacturing method according to claim 18,
wherein the processor reads the first intermediate function from a storage medium in which the first intermediate function obtained by performing Fourier transform on a result of deconvolution of the aerial image function with the instrument function, calculates a second intermediate function obtained by performing Fourier transform on the measurement waveform, calculates a product of the first intermediate function and the second intermediate function, and calculates the convolution spectrum waveform by performing inverse Fourier transform on the product.
